(19) United States
(12) Patent Application Publication
(10) Pub. No.: US 2024/0272546 A1
(43) Pub. Date: Aug. 15, 2024

(54) Lithographically Integrated Dot Projector

(71) Applicants: Wei Ting Chen, Plainsboro, NJ (US); Qing Wang, Plainsboro, NJ (US)

(72) Inventors: Wei Ting Chen, Plainsboro, NJ (US); Qing Wang, Plainsboro, NJ (US)

(21) Appl. No.: 18/441,915

(22) Filed: Feb. 14, 2024

Related U.S. Application Data
(60) Provisional application No. 63/445,632, filed on Feb. 14, 2023.

(51) Int. Cl. G03F 7/00; G01B 11/25; G02B 1/00; G06V 40/16; H01S 5/42

(52) U.S. Cl. CPC G03F 7/0005; G01B 11/2513; G02B 1/002; G06V 40/16; H01S 5/423; G02B 2207/101

(57) ABSTRACT

A dot pattern projector and its associated method of manufacture. The dot pattern projector utilizes VCSEL diodes that shine infrared light through a transparent layer. The VCSEL diodes can be formed directly onto the transparent layer or onto a substrate that is in contact with the transparent layer. The VCSEL diodes are lithographically formed into a matrix, wherein each of the VCSEL diodes shines a cone of infrared light into and through the transparent layer. Each cone of infrared light intersects at least one other cone of infrared light within the transparent layer. A dielectric layer covers the transparent layer. The dielectric layer reduces reflections at the second surface of the transparent layer. A metasurface is formed on the dielectric layer. The metasurface converts the light passing through the dielectric layer into a specific dot pattern or other such pattern.

### RELATED APPLICATIONS

This application claims the benefit of U.S. Provisional Patent Application No. 63/445,632, filed Feb. 14, 2023.

### BACKGROUND OF THE INVENTION

### 1. Field of the Invention

In general, the present invention relates to dot projectors that are used to create a dot pattern on a surface for use in mapping the contours of the surface. More particularly, the present invention relates to solid state dot projectors that utilize infrared light produced by a matrix of vertical-cavity surface-emitting laser (VCSEL) diodes and a metasurface.

### 2. Prior Art Description

The use of a projected dot pattern is commonly used to map the contours of a surface. For example, many smart phones, tablets, and other electronic devices have the ability to identify a person using facial recognition, based upon mapping a projected dot pattern. In order to project a dot pattern an infrared laser dot projector is used to project the dot pattern and an infrared camera is used to image the pattern. The laser dot projector projects a grid of small infrared dots onto a surface. Once the infrared camera images the projected dot pattern, software reads the resulting pattern and generates a 3D map. The 3D map can be compared with known patterns to determine if the subject being imaged is the same. Such comparisons are used for facial recognition, product inspection, and the like.

On many modern devices, a dot projector is utilized to project thousands of infrared dots onto a surface. The infrared dots are typically produced using a matrix of VCSEL diodes. However, the light produced by the VCSEL diodes is not projected directly onto the surface. Rather, the light from the matrix of VCSEL diodes is first passed through optical elements to collimate, focus, or otherwise conditioned laser light being produced. The conditioned light is then passed through diffractive optical elements that divide the laser light beam into thousands of distinct sub-beams. When a dot projector illuminates an object, these sub-beams create light dots on the object surface. A dot projector is designed to form a predetermined dot pattern when projecting light beams onto a flat surface.

The dot pattern is altered as it is projected onto a contoured surface. The resulting surface morphology is then imaged using an infrared camera. The morphology of the dots is compared to a predetermined pattern to determine if there is a dot pattern match. A dot pattern match indicates that a surface has the shape that it should. This enables facial recognition, part inspection recognition and the like.

Producing a dot projector that can accurately produce and project the needed dot pattern is highly complicated. Typically, the VCSEL diode matrix is manufactured separately from the light conditioning elements and the diffractive optical elements. Such a structure is exemplified in U.S. Patent Application Publication No. 2023/0213726 to Graff. As a result, during manufacture, the light conditioning elements and the diffractive optical elements must be assembled and aligned with the VCSEL diode matrix and then the assembly tested. If the alignment is off, the assembly must be scrapped and replaced. This testing procedure is redundant, slow, and usually costs more than manufacturing the components.

In an attempt to simplify manufacturing and testing, the light conditioning elements and the diffractive optical elements have been integrated into a single construction. This is typically accomplished by printing and etching a metasurface onto a substrate. The substrate and metasurface act together to form a dot pattern or other diffusion pattern. Such construction is exemplified in U.S. Pat. No. 11,327,204 to You, and U.S. Pat. No. 11,579,456 to Riley. However, since the metasurface/substrate assembly is still separate and distinct from the VCSEL diode matrix, the two components must still be assembled, aligned, and tested. Accordingly, the same problems remain.

In order to eliminate the need for assembly and alignment, the VCSEL diode matrix, light conditioning elements, and the diffractive optical elements have to be integrated into one semiconductor chip that can be tested on-chip at the point of chip manufacture. However, such an integrated chip has proven very difficult to produce.

In U.S. Pat. No. 11,762,212 to Downing, an attempt to integrate optical elements onto a VCSEL diode matrix is shown. The Downing patent discloses a flood light illuminator and does not disclose a system for dot projection. However, in the Downing patent, the VCSEL diode matrix is formed atop a base substrate in a traditional manner. The VCSEL diode matrix shines light away from the base substrate. The light from the VCSEL diode matrix shines into a transparent substrate that is formed atop the VCSEL diode matrix. A metasurface is formed atop the transparent substrate to diffuse the light. Although the assembly is produced as a single semiconductor construct, the semiconductor device is less efficient than prior art multi-part constructions. The ratio between the thickness of the transparent substrate and the spacing of the VCSEL diodes prevents the light from the VECEL diodes from overlapping prior to reaching the metasurface. Furthermore, due to differences in the indices of refraction, the transition from the transparent substrate to the metasurface generates reflections in the impinging light. Since the light originates from multiple points, multiple reflections travel back into the transparent substrate. This causes interference with the light propagating from the VCSEL diodes. The result is that the intensity of the light reaching the metasurface is reduced in areas by a significant degree due to the combination of light reflection and light interference. Although such interference patterns are negligible in a flood light, they are highly problematic when attempting to project a precise dot pattern. Furthermore, in order to compensate for the loss in light intensity, more power must be provided to the VCSEL diodes. This causes the VCSEL diodes to run hotter. Since the VCSEL diodes are trapped between the base substrate and the transparent substrate, the VCSEL diodes are insulated and retain heat. Consequently, the efficiencies of the VCSEL diodes are further reduced as higher operational temperatures are reached.

A need therefore exists for a dot projector that uses VCSEL diodes, yet is a unit with an integrated semiconductor construction and wherein the VCSEL efficiency is at least as good as multipiece prior art dot projector assemblies. In this manner, assembly, alignment, and testing can be eliminated or greatly simplified without loss of optimal performance. This need is met by the present invention as described and claimed below.

### SUMMARY OF THE INVENTION

The present invention is a dot pattern projector and its associated method of manufacture. The dot pattern projector is used in electronics for mapping a surface, such as the face of an individual. The dot pattern projector utilizes VCSEL diodes that shine infrared light through a transparent layer. The VCSEL diodes can be formed directly onto the transparent layer or onto a substrate that is in contact with the transparent layer.

The VCSEL diodes are lithographically formed into a matrix, wherein each VCSEL diode shines a cone of infrared light into and through the transparent layer. The VCSEL diodes are oriented within the matrix so that each cone of infrared light intersects at least one other cone of infrared light within the transparent layer.

A dielectric layer covers the transparent layer on the surface opposite the VCSEL diodes. The dielectric layer is transparent to frequencies of infrared light produced by the VCSEL diodes. The dielectric layer reduces reflections at the second surface of the transparent layer. As such, the infrared light can pass through the transparent layer and the dielectric layer with less loss.

A metasurface is formed on the dielectric layer. The metasurface converts the light passing through the dielectric layer into a specific dot pattern or other such pattern. The light pattern is then projected forward toward a target surface. The metasurface can be encapsulated in a transparent material for structural support.

### BRIEF DESCRIPTION OF THE DRAWINGS

For a better understanding of the present invention, reference is made to the following description of exemplary embodiments thereof, considered in conjunction with the accompanying drawings, in which:

FIG. 1 shows a first exemplary embodiment of a dot projector construct shown in conjunction with an exemplary dot projection;

FIG. 2 is an exploded view of the exemplary embodiment shown in FIG. 1;

FIG. 3 shows a graph illustrating the increase in light efficiency created by the dielectric layer within the dot projector construct;

FIG. 4 is a block diagram outlining an exemplary method of manufacturing the exemplary dot projector construct of FIG. 1;

FIG. 5 shows a second exemplary embodiment of a dot projector construct; and

FIG. 6 shows an optional manufacturing detail that can be integrated into either the first exemplary embodiment of FIG. 1 and/or the second exemplary embodiment of FIG. 5.

### DETAILED DESCRIPTION OF THE DRAWINGS

Although the present invention device and methodology can be embodied in many ways, only a few exemplary embodiments are illustrated. The exemplary embodiments are being shown for the purposes of explanation and description. The exemplary embodiments are selected in order to set forth some of the best modes contemplated for the invention. The illustrated embodiments, however, are merely exemplary and should not be considered limitations when interpreting the scope of the appended claims.

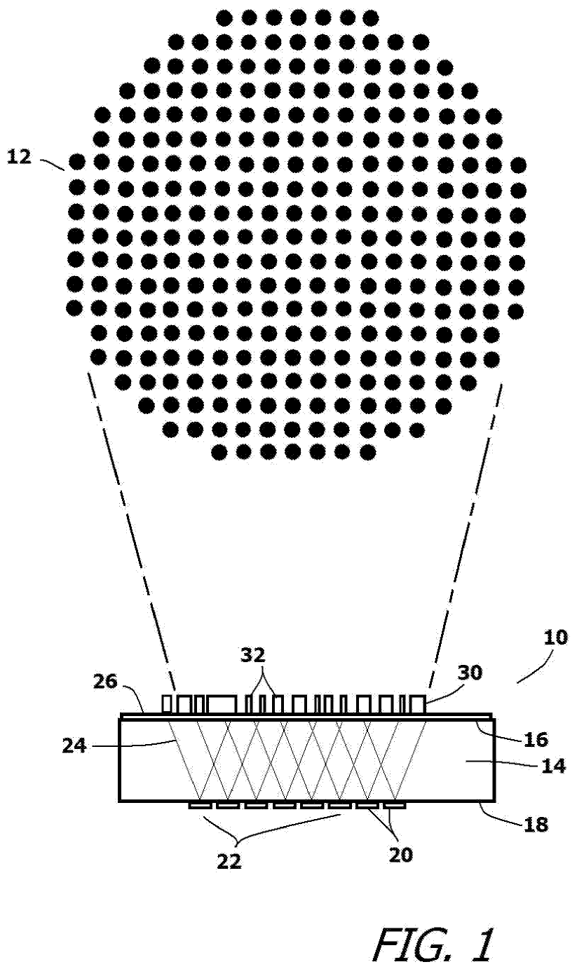

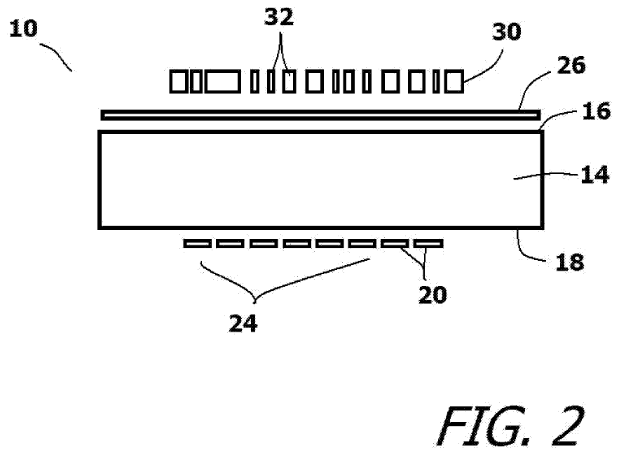

Referring to FIG. 1 and FIG. 2, a semiconductor construct 10 is shown that is capable of producing a dot pattern 12, line pattern, diffraction pattern or the like. In the illustrated embodiment, a dot pattern 12 is shown by way of example. The semiconductor construct 10 has a transparent layer in the form of a base substrate 14. The base substrate 14 has a top surface 16 and a bottom surface 18. Between the top surface 16 and the bottom surface 18, the base substrate 14 is preferably no greater than one millimeter thick. The base substrate 14 is preferably a gallium arsenide (GaAs) wafer with distributed Bragg reflectors formed from GaAs and aluminum gallium arsenide. However, other substrates that are transparent to the wavelengths of light produced by the VCSEL diodes 20 can also be used.

A plurality of VCSEL diodes 20 are formed into a VCSEL matrix 22 directly on the bottom surface 18 of the base substrate 14. The VCSEL diodes 20 are formed in an inverted configuration so that the VCSEL diodes 20 shine infrared light into and through the base substrate 14. The base substrate 14 is transparent to the wavelengths of infrared light produced by the VCSEL diodes 20, accordingly the passage of the light through the base substrate 14 causes negligible losses in light intensity. Since the VCSEL diodes 20 are on the bottom surface 18 of the base substrate 14, the VCSEL diodes 20 are exposed as they operate. In this manner, the VCSEL diodes 20 can be effectively cooled by air flow or contact with a heat sink (not shown). Accordingly, the optimal operating temperature range of the VCSEL diodes 20 can be maintained, regardless of activation time or battery current.

Each VCSEL diode 20 produces a cone of infrared light 24. Each cone of infrared light 24 diverges from the VCSEL diode 20 through the base substrate 14 with an inherent dispersion angle. The VCSEL diodes 20 are arranged and spaced in the VCSEL matrix 22 so that the cones of infrared light 24 from adjacent VCSEL diodes 20 overlap within the base substrate 14. The preferred degree of overlap between the cones of infrared light 24 from adjacent VCSEL diodes 20 is preferably between ten percent and fifty percent. The overlap in the cones of the infrared light 24 allows the VCSEL diodes 20 to be packed denser in the VCSEL matrix 22. This provides higher power outputs and better contrast.

Due to the overlap in the cones of infrared light 24, the top surface 16 of the base substrate 14 is internally illuminated over the whole of the VCSEL matrix 22. The base substrate 14 is preferably gallium arsenide, which has a refractive index of approximately 3.5 at the wavelength of 940 nm. A dielectric layer 26 is used to coat the top surface 16 of the base substrate 14. The dielectric layer 26 is preferably a layer of silicon nitride having a thickness of no greater than 400 nanometers and a refractive index of less than 2.3. With the dielectric layer 26 in place, the reflection of the propagating infrared light at the top surface 16 of the base substrate 14 is greatly reduced. This results in the intensity of light passing through the base substrate 14 being comparable to prior art systems that utilize gap spaces above the VCSEL substrate.

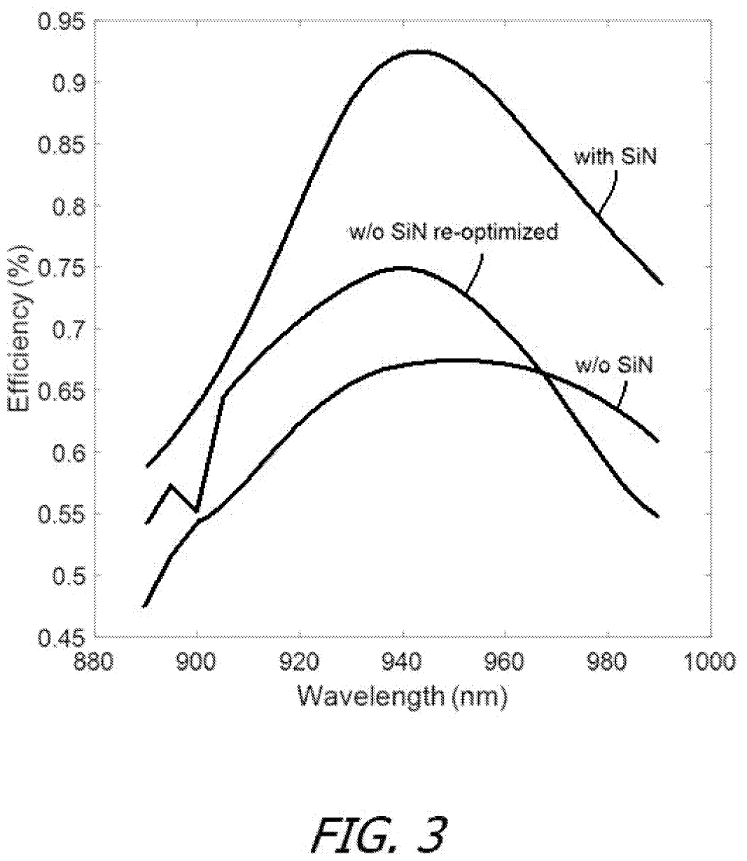

Referring to FIG. 3 in conjunction with FIG. 1 and FIG. 2, it can be seen that with the dielectric layer 26 in place, the overall efficiency in the passage of light is greatly increased in the working frequencies between 900 nm and 990 nm. The maximum efficiency without the dielectric layer 26 reaches a maximum just below 75 percent. While the maximum efficiency with the dielectric layer 26 reaches a maximum just above 93 percent. This represents an increase in efficiency of over 18 percent.

In addition to helping reduce internal reflection, the presence of the dielectric layer 26 helps in binding a metasurface 30 to the base substrate 14. The metasurface 30 is lithographically deposited onto the dielectric layer 26. The metasurface 30 consists of nanopillars 32 of amorphous silicon. The nanopillars 32 each have a height, a peripheral shape, and a peripheral size. Preferably, the height of the different nanopillars 32 is the same. However, different nanopillars 32 can have different peripheral sizes and/or shapes to produce dots or other optical features of different shapes, sizes, and patterns. The metasurface 30 is aligned and fabricated by a lithography system using the same manufacturing technique used for making the VCSEL matrix 22. The metasurface 30 provides the functionalities of the light conditioning elements and the diffractive optical elements used in the prior art. That is, the metasurface 30 collimates the infrared light, splits, and directs the infrared light into the dot pattern 12. Since the metasurface 30 is applied using lithography atop the dielectric layer 26 and base substrate 14, great positional tolerances can be maintained. The alignment tolerance between the metasurface 30 above the base substrate 14 and the VCSEL diodes 20 below the base substrate 14 can be held under a micrometer. Accordingly, defects due to alignment and/or assembly are eliminated. Also, because the metasurface 30 and underlying VCSEL matrix 22 are integrated on the same wafer, high throughput wafer scale testing can be conducted.

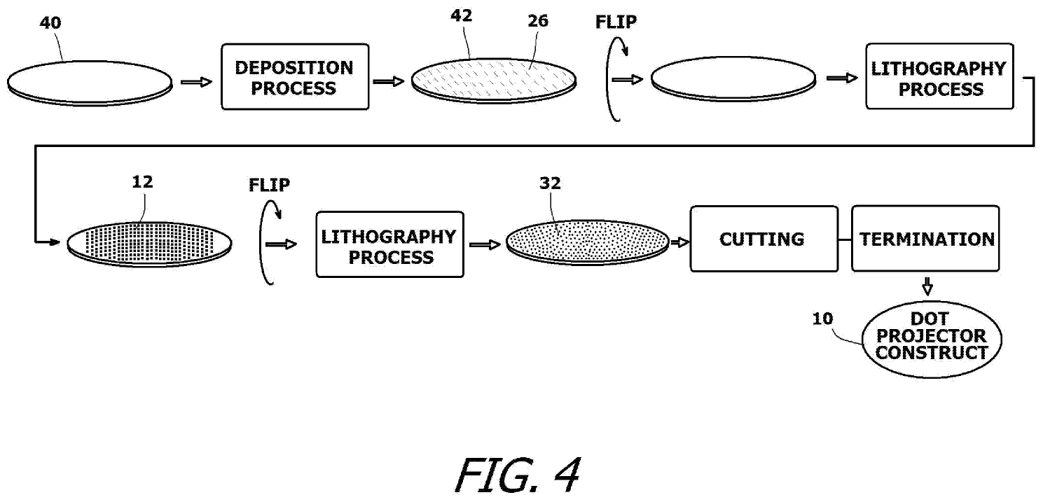

Referring to FIG. 4 in conjunction with FIG. 1 and FIG. 2, it will be understood that to manufacture the present invention, a wafer 40 of gallium arsenide is provided. The wafer 40 is coated on one side with silicon nitride or a material with similar optical and electrical properties to produce the dielectric layer 26. The coated wafer 42 is used as the substrate in a semiconductor lithography process. The semiconductor lithography process first creates the VCSEL diodes 20 on the uncoated side of the coated wafer 42. Although the process of lithographically forming the VCSEL diodes 20 is known, the density of the VCSEL diodes 20 is calculated as a function of the light produced by the VCSEL diodes 20 so that the cones of infrared light 24 generated by the VCSEL diodes 20 overlap when propagating through the material of the coated wafer 42.

After the VCSEL diodes 20 are formed, the coated wafers 42 are flipped and the nanopillars 32 are formed onto the dielectric layer 26. The resulting projector constructs 10 can be inspected and tested on-wafer. Alternatively, the projector constructs 10 can be cut to size and tested after leads are connected to the projector constructs 10.

It will be understood that the steps shown in FIG. 4 can also be arranged in a different sequence in fabrication processes. For example, the dielectric layer 26 can be coated after VCSEL diodes 20 are formed.

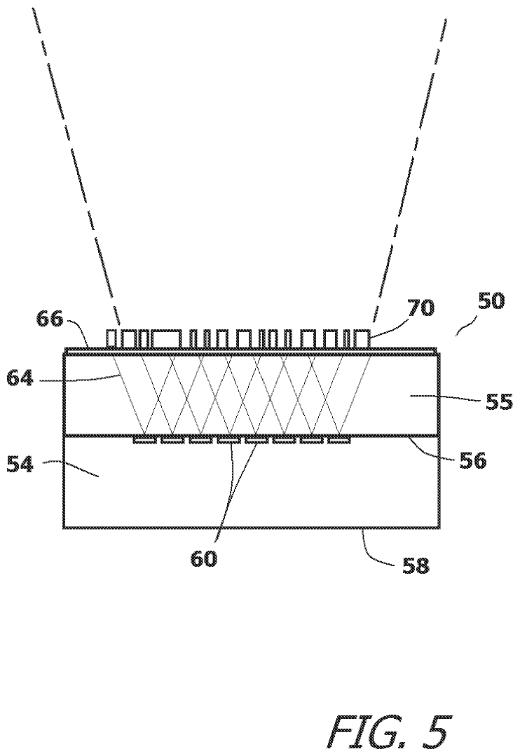

Referring to FIG. 5, an alternate embodiment of a semiconductor construct 50 is shown that is capable of producing a dot pattern, line pattern, diffraction pattern or the like. The semiconductor construct 50 has a base substrate 54. The base substrate 54 has a top surface 56 and a bottom surface 58. Between the top surface 56 and the bottom surface 58, the base substrate 54 is preferably no greater than one millimeter thick. The base substrate 54 is preferably a gallium arsenide (GaAs) wafer with distributed Bragg reflectors formed from GaAs and aluminum gallium arsenide. However, other substrates can also be used.

A plurality of VCSEL diodes 60 are formed on the top surface 56 of the base substrate 54. The VCSEL diodes 60 are formed so that the VCSEL diodes 60 shine infrared light up and away from the base substrate 54. A transparent layer 55 is formed atop the base substrate 54 and the VCSEL diodes 60. The layer 55 is transparent to the wavelengths of infrared light produced by the VCSEL diodes 60. Furthermore, the coefficient of thermal expansion for the transparent layer 55 is matched as closely as possible to the coefficient of thermal expansion inherent in the base substrate 54. As a result, the transparent layer 55 can be one of several glass types, such as silicon oxide, titanium oxide, lead oxide, potassium oxide, zinc oxide, boron oxide, aluminum oxide and fluorite, depending upon the composition of the base substrate 54. In this manner, the heat generated by the VCSEL diodes 60 effect the transparent layer 55 and the base substrate 54 in the same manner, preventing stresses that could damage the VCSEL diodes 60.

Each VCSEL diode 60 produces a cone of infrared light 64. Each cone of infrared light 64 diverges from the VCSEL diode 60 through the transparent layer 55 with an inherent dispersion angle. The VCSEL diodes 60 are arranged and spaced so that the cones of infrared light 64 from adjacent VCSEL diodes 60 overlap within the transparent layer 55. The preferred degree of overlap between the cones of infrared light 64 from adjacent VCSEL diodes 60 is preferably between ten percent and fifty percent, therein providing for higher power outputs and better contrast.

A dielectric layer 66 covers the transparent layer 55. The dielectric layer 66 is preferably a layer of silicon nitride, or other materials such as silicon oxide, titanium oxide and aluminum oxide. With the dielectric layer 66 in place, the reflection of the propagating infrared light at the interface with the transparent layer 55 is greatly reduced.

A metasurface 70 is formed atop the dielectric layer 66 to structure the light that passes through the dielectric layer 66. The metasurface 70 structures the light into a dot pattern or other useful light pattern.

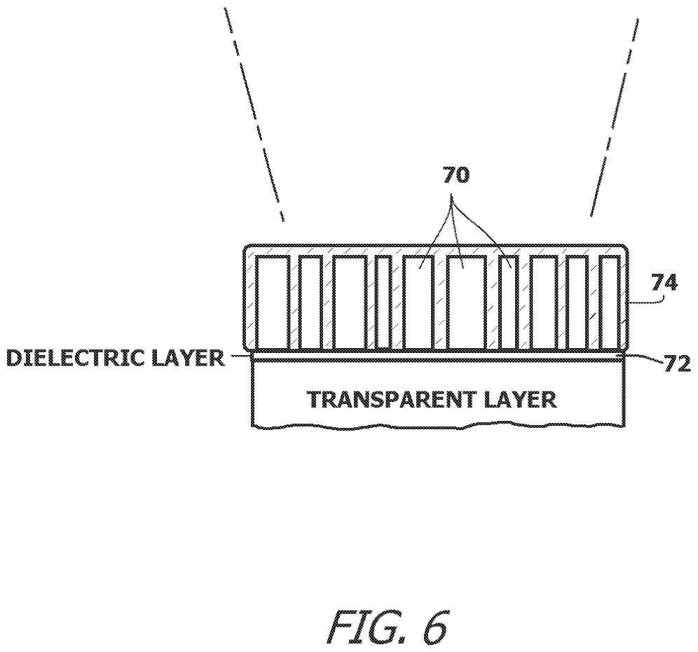

In the embodiments of FIG. 1 and FIG. 5, the metasurface is exposed. This can lead to contact damage. In FIG. 6, an optional manufacturing step is shown that can be used on either described embodiment. Referring to FIG. 6. It can be seen that a metasurface 70 is formed on a dielectric surface 72. The metasurface 70 and the dielectric surface 72 are of the type previously described.

The metasurface 70 can be encapsulated in a protective layer 74 of silicon nitride, silicon oxide, aluminum oxide or a polymer material whose index of refraction no greater than 2. The material selected for the protective layer 74 is transparent to the frequencies of light passing being structured by the metasurface 70. The protective layer 74 will have some optical effect upon the passing light. Accordingly, the optical effects of the metasurface 70 and the protective layer 74 can be designed together to produce the wanted structuring of light.

It will be understood that the embodiments of the present invention that are illustrated and described are merely exemplary and that a person skilled in the art can make many variations to those embodiments. All such embodiments are intended to be included within the scope of the present invention as defined by the claims.

What is claimed is:

1. A dot pattern projection construct, comprising:
a substrate having a first surface and an opposite second surface, wherein said substrate is transparent to at least some frequencies of infrared light;
VCSEL diodes formed into a matrix directly on said first surface of said substrate, wherein each of said VCSEL diodes shines a cone of infrared light into and through said substrate, wherein said VCSEL diodes are oriented in said matrix so that each said cone of infrared light intersects at least one other within said substrate;
a dielectric layer covering said second surface of said substrate, wherein said dielectric layer is transparent to said at least some frequencies of infrared light; and
a metasurface formed on said dielectric layer, wherein said dielectric layer is interposed between said metasurface and said substrate.

2. The construct according to claim 1, wherein said substrate is a gallium arsenide substrate having a thickness between said first surface and said second surface of no greater than two millimeters.

3. The construct according to claim 1, wherein said dielectric layer is a layer selected from a group comprising silicon nitride, silicon oxide, titanium oxide and aluminum oxide.

4. The construct according to claim 3, wherein said dielectric layer has a thickness no greater than 400 nanometers.

5. The construct according to claim 1, wherein said matrix is configured to make each said cone of infrared light overlap another said cone of infrared light in an overlap range typically between ten percent and fifty percent.

6. The construct according to claim 1, wherein said metasurface is a plurality of nanocylinders lithographically fabricated onto said dielectric layer.

7. The construct according to claim 1, further including a protective layer that encapsulates at least some of said nanocylinders, wherein said protective layer is selected from a group of material that include silicon nitride, silicon oxide, aluminum oxide and a polymer material, wherein said material has an index of refraction no greater than 2.

8. A pattern projection construct, comprising:
a transparent layer having a first surface and an opposite second surface;
a plurality of infrared diodes in contact with said first surface of said transparent layer, wherein said plurality of infrared diodes produce infrared light that shines directly into and through said transparent layer;
a dielectric layer covering said transparent layer on said second surface of said transparent layer, wherein said dielectric layer is transparent to said infrared light; and
a metasurface formed on said dielectric layer for structuring said infrared light, wherein said dielectric layer is interposed between said metasurface and said transparent layer.

9. The construct according to claim 8, wherein each of said plurality of infrared diodes shines a cone of infrared light into and through said transparent layer, wherein said plurality of infrared diodes are positioned so that each said cone of infrared light intersects at least one other within said transparent layer.

10. The construct according to claim 8, wherein said plurality of infrared diodes are formed on a substrate under said transparent layer.

11. The construct according to claim 8, wherein said dielectric layer is a layer of material selected from a group comprising silicon nitride, silicon oxide, titanium oxide and aluminum oxide.

12. The construct according to claim 8, wherein said transparent layer is a layer of material selected from a group comprising silicon oxide, titanium oxide, lead oxide, potassium oxide, zinc oxide, boron oxide, aluminum oxide and fluorite.

13. The construct according to claim 8, wherein each said cone of infrared light overlaps another said cone of infrared light in said transparent layer in an overlap range typically between ten percent and fifty percent.

14. The construct according to claim 8, wherein said metasurface is a plurality of nanocylinders made from amorphous silicon.

15. The construct according to claim 14, further including a protective layer that encapsulates at least some of said nanocylinders, wherein said protective layer is selected from a group of material that include silicon nitride, silicon oxide, aluminum oxide and a polymer material, having an index of refraction no greater than 2.

16. A method of manufacturing a semiconductor construct for producing a dot pattern projection, comprising:
providing a transparent layer having a first surface and an opposite second surface, wherein said transparent layer is transparent to at least some frequencies of infrared light;
covering said second surface of said transparent layer with a dielectric layer, wherein said dielectric layer is transparent to said at least some frequencies of infrared light;
positioning a matrix of VCSEL diodes in contact with said first surface of said transparent layer, wherein each of said VCSEL diodes is oriented to shine a cone of infrared light into and through said transparent layer,
lithographically forming a metasurface on said dielectric layer, wherein said dielectric layer is interposed between said metasurface and said transparent layer.

17. The method according to claim 16, further including orienting said VCSEL diodes in said matrix so that each of said VCSEL diodes will produces a cone of infrared light that will intersects at least one other said cone of infrared light within said transparent layer.

18. The method according to claim 16, wherein said dielectric layer is a layer of material selected from a group comprising silicon nitride, silicon oxide, titanium oxide and aluminum oxide.

19. The method according to claim 17, wherein said transparent layer is a layer of material selected from a group comprising silicon oxide, titanium oxide, lead oxide, potassium oxide, zinc oxide, boron oxide, aluminum oxide and fluorite.

20. The method according to claim 17, further including encapsulating said metasurface in a material having an index of refraction is no greater than 2.
